(19) United States
(12) Patent Application Publication
(10) Pub. No.: US 2026/0297792 A1
(43) Pub. Date: Oct. 1, 2026

(54) GROWTH DEVICE AND GROWTH METHOD FOR OBTAINING LARGE-SIZED SINGLE CRYSTAL MATERIAL BASED ON SOLVENT EVAPORATION METHOD

(71) Applicant: SHANDONG UNIVERSITY, Qingdao City (CN)

(72) Inventors: Changfeng FANG, Qingdao City (CN); Jiezhao LV, Qingdao City (CN); Peng SUN, Qingdao City (CN); Dexiao FANG, Qingdao City (CN); Lili WANG, Qingdao City (CN); Lu DENG, Qingdao City (CN); Xian ZHAO, Qingdao City (CN)

(21) Appl. No.: 19/552,081

(22) Filed: Feb. 27, 2026

(30) Foreign Application Priority Data
Mar. 26, 2025 (CN) 202510360741.9

(51) Int. Cl. C30B 7/04; C30B 29/14

(52) U.S. Cl. CPC C30B 7/04; C30B 29/14

(57) ABSTRACT

Provided are a growth device and a growth method for obtaining a large-sized single crystal material based on a solvent evaporation method, belonging to the technical field of crystal growth. An evaporation crystallizer includes a solution evaporation tank, a crystal growth tank, and a funnel-shaped structure through which the solution evaporation tank communicates with the crystal growth tank. A cavity for containing growth solution is formed in the evaporation crystallizer. An upper part of the solution evaporation tank is provided with an opening. A seed crystal fixing groove is arranged at a bottom of the crystal growth tank. A plate-shaped cavity is formed in the crystal growth tank. An arrayed electric heating temperature control device includes heating elements and temperature sensing elements. The heating elements and the temperature sensing elements are arranged in groups as a vertical array on an outer side of the evaporation crystallizer.

### CROSS-REFERENCE TO RELATED APPLICATION

This patent application claims the benefit and priority of Chinese Patent Application No. 202510360741.9 filed with the China National Intellectual Property Administration on Mar. 26, 2025, the disclosure of which is incorporated by reference herein in its entirety as part of the application.

### TECHNICAL FIELD

The present disclosure belongs to the technical field of a crystal growth device, and in particular to, a growth device and a growth method for obtaining a large-sized and specially-oriented single crystal material based on a solvent evaporation method.

### BACKGROUND

A potassium dihydrogen phosphate (a chemical formula KH₂PO₄, abbreviated as KDP) crystal is a nonlinear optical material with excellent performance, and has the advantages of a large nonlinear optical coefficient, a wide transmission band, a high laser-induced damage resistance and easy growth of a large-aperture single crystal, thereby being widely used in the lasers. The KDP crystal is the only nonlinear optical crystal that may be used in Inertial Confinement Fusion (ICF). At present, the main growth methods is still the conventional cooling method and the rapid growth method.

The conventional cooling method of growth indicates that growth solution is cooled to allow the solution to be in a supersaturated state, which provides a driving force for crystal growth. Under low supersaturation, the crystal grows along its crystal Z-axis, the growth rate is 1 mm/d to 2 mm/d, requiring period for growing a large-sized KDP single crystal is 1 to 2 years, which is not conducive to improving the application efficiency. The rapid growth method refers to a “point seed crystal” rapid growth method. Through rapid cooling, the seed crystal grows omni-directionally in a high supersaturation solution environment, and a pyramid face and a prismatic face expand at the same time. As a result, the growth rate can be accelerated to 15-20 mm/d. However, there's a problem in the crystals obtained by the rapid growth method: the fan-shaped boundaries. In addition, the lattice near an interface between the pyramid face and the prismatic face of the crystal always has specific distortion, thereby affecting performance of a passing beam and leading to decrease of a crystal utilization rate. Although both methods can obtain KDP-like single crystal with a large sizes, they have the following disadvantages: first, the KDP crystals grow predominantly along the natural crystal axes. When used for nonlinear optical devices, the KDP crystals must be cut along a specific direction to meet a phase matching condition, while irreversible damage is easily caused by wire cutting machines due to heat accumulation during post-processing; second, a maximal utilization rate of raw materials in the solution is only 39.5% in a conventional growth cooling range, failing to utilize all raw materials for crystal growth, and therefore, this method requires a solution volume several times that of the evaporation method, resulting in significant disadvantages in terms of a volume and an occupied area of the growth container; and third, although the growth rate has been improved to some extent in the rapid growth method, the pyramid face and the prismatic face of the crystal expand at the same time, resulting in larger corner region that are necessarily wasted when cutting along a phase matching direction, thereby seriously reducing a utilization rate of the crystal.

### SUMMARY

In order to solve the problems existing in the prior art, the present disclosure provides a growth device and a growth method for obtaining a large-sized single crystal material based on a specifically designed growth vessel using the solvent evaporation method. A crystal orientation selective evaporation crystallizer is used for directional crystal growth, so that a KDP crystal along a specific phase matching direction can grow rapidly with a much higher rate of raw materials utilization than that of a conventional cooling growth method. As such, the crystallizer footprint is reduced, raw materials of the crystal are saved, mechanical cutting in the later stage is avoided, and a crystal yield is improved.

The present disclosure uses the following technical solution to solve the technical problem. A specially-designed growth device for obtaining a large-sized single crystal material based on a solvent evaporation method includes an evaporation crystallizer and an arrayed electric heating temperature control device. The evaporation crystallizer includes a solution evaporation tank, a crystal growth tank, and a funnel-shaped structure through which the solution evaporation tank communicates with the crystal growth tank. A cavity for containing growth solution is formed in the evaporation crystallizer. An upper part of the solution evaporation tank is provided with an opening. A seed crystal fixing groove is arranged at a bottom of the crystal growth tank. A plate-shaped cavity is formed in the crystal growth tank. The arrayed electric heating temperature control device includes heaters and temperature sensors, which are arranged in groups as a vertical array on an outer side of the evaporation crystallizer.

In some embodiments, an interval between the heaters in the vertical array is not more than 3 cm.

In some embodiments, the heaters are polyimide film heaters with a width of no more than 2 cm.

In some embodiments, the heaters are connected to a DC power supply, the temperature sensors establish signal connection with a microcomputer through a temperature transmitter, and the DC power supply is connected to the microcomputer.

In some embodiments, the temperature sensors are thermistor sensors attached to the outside of the heaters.

In some embodiments, the opening of the solution evaporation tank is covered with a semi-permeable membrane, and a pore size of the semi-permeable membrane is less than 100 nanometers.

In some embodiments, the evaporation crystallizer includes a front plate and a back plate connected through flanges.

A single crystal directional growth method is provided, including the following steps:
S1, placing a seed crystal with a specific orientation in a seed fixing groove, assembling and sealing a front plate and a back plate through connecting flanges, and attaching heaters and temperature sensors in array to an outer side surface of an evaporation crystallizer;
S2, injecting saturated solution of a crystal material into a solution evaporation tank, covering a top of the solution evaporation tank with a semi-permeable membrane, and adjusting an arrayed electric heating temperature control device according to the height of the crystal to meet growth temperature gradient distribution;
S3, gradually reducing the saturated solution in the solution evaporation tank with evaporation until the saturated solution is completely consumed, providing a growth driving force for the seed crystal in a confined crystal growth tank to continuously grow, simultaneously, limiting a growth space of the seed crystal in a specific direction until the seed crystal grows into a large-sized single crystal with a special shape, and after growth, disassembling and separating the back plate of the evaporation crystallizer to finally obtain a large-sized specially-oriented single crystal product required by a customer.

In some embodiments, adjusting an arrayed electric heating temperature control device according to an actual height of a crystal to meet growth temperature gradient distribution includes: detecting temperatures through the temperature sensors and sending measured temperature data to a microcomputer in a Modbus RTU protocol through an RS485 interface, controlling an output voltage of a DC power supply by the microcomputer through a computer program according to received temperature data to change output powers of the heaters and finally adjust the temperature distribution.

In some embodiments, the computer program for controlling the DC power supply needs to achieve temperature distribution as follows: a temperature corresponding to supersaturation of −10% to −15% at 12 cm to 15 cm above the crystal gradually decreases to a temperature corresponding to supersaturation of 5% to 10% on a surface of the crystal.

Compared with the prior art, embodiments of the present disclosure achieve the following beneficial effects. The plate-shaped cavity is arranged in the crystal growth tank to provide a large-sized crystal growth space with a specific shape, mechanical cutting is not needed, and the waste of useless crystals is reduced. The arrayed electric heating temperature control device is computer controlled. The entire device is in a static condition, with easy global growth control, resulting in convenient operation and high growth stability. A solvent evaporation method is used, which makes the utilization rate of raw materials high. The present disclosure not only solves the problems existing in the conventional crystal growth technology, but also provides a new method for the growth of high-quality large size single crystalline KDP samples with specific orientations and shapes. The present disclosure has unique technical advantages and high market competitiveness, and is simple in structure, small in device volume, and low in production costs.

### BRIEF DESCRIPTION OF THE DRAWINGS

FIG. 1 is a structural diagram of an evaporation crystallizer and an arrayed electric heating temperature control device according to the present disclosure.

FIG. 2 is a schematic diagram of a seed placement tank and a growth direction according to the present disclosure.

In the drawings: 1 solution evaporation tank, 2 growth solution, 3 crystal growth device main body, 4 seed crystal, 5 front plate, 6 back plate, 7 crystal growth tank, 8 funnel-shaped structure, 9 film heater, 10 thermistor sensor, 11 temperature transmitter, 12 DC power supply, 13 microcomputer, 14 temperature control device, 15 rectangular groove.

### DETAILED DESCRIPTION OF THE EMBODIMENTS

In order to facilitate the understanding of the present disclosure, the present disclosure will be described in more detail with reference to the drawings and specific embodiments. However, the present disclosure can be achieved in many different forms and is not limited to the embodiments described in this specification. On the contrary, these embodiments are provided to allow the present disclosure to be understood more thoroughly and comprehensively.

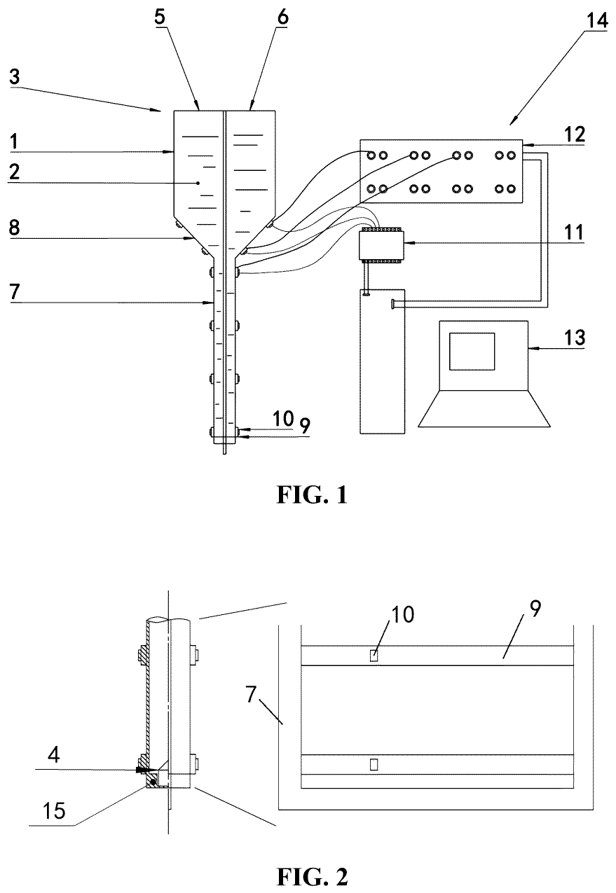

A growth device for obtaining a large-size KDP single crystal material based on a solvent evaporation method includes: an evaporation crystallizer and an arrayed electric heating temperature control device 14. The evaporation crystallizer includes a solution evaporation tank 1 located on the upper part, a crystal growth tank 7 located on a lower part, and a funnel-shaped structure 8 through which the solution evaporation tank 1 communicates with the crystal growth tank 7. A cavity for growth solution 2 is formed in the evaporation crystallizer. The upper part of the solution evaporation tank 1 has an opening. A seed crystal fixing groove is arranged at the bottom of the crystal growth tank 7. The use of the seed crystal fixing groove can ensure the application of the seed crystal with a specific orientation and has specific ability to protect the seed crystal 4 from being deformed. A plate-shaped cavity is formed in the crystal growth tank 7. The plate-shaped cavity has a shape-limiting functionality, and can limit the growth shape of a single crystal material in one or more directions for obtaining a single crystal with an unconventional shape such as a thin plate, so that the overall production efficiency can be improved. The arrayed electric heating temperature control device 14 includes heaters and temperature sensors, which are arranged in groups as a vertical array on an outer side of the evaporation crystallizer. The evaporation crystallizer is understood with reference to the crystal growth device main body 3 in FIG. 1.

In an embodiment, an interval between the heaters in the array is not more than 3 cm.

In an embodiment, the heaters are polyimide film heaters 9 with a width of no more than 2 cm.

In an embodiment, the heaters are connected to a DC power supply 12, the temperature sensors establish signal connection with a microcomputer 13 through a temperature transmitter 11, and the DC power supply 12 is connected to the microcomputer 13.

In an embodiment, the temperature sensors are thermistor sensors 10, and the thermistor sensors 10 are attached to outer sides of the heaters.

In an embodiment, the opening of the solution evaporation tank 1 is covered with a semi-permeable membrane, and a pore size of the semi-permeable membrane is less than 100 nanometers. In this way, an external environment can be prevented from disturbing the growth solution 2 while ensuring evaporation and escape of solvent molecules, and stability of the growth process can be improved.

In an embodiment, the evaporation crystallizer includes a front plate 5 and a back plate 6 connected through flanges. The front plate 5 can be connected to the back plate 6 through a silica gel sealing strip and a G-shaped clamp, and the front plate 5 as well as the back plate 6 can be disassembled independently, thereby ensuring independence and stability of the crystal growth environment, and reducing difficulty in disassembling and assembling the crystal.

A single crystal directional growth method is provided, including the following steps:
S1, placing a seed crystal 4 with a specific orientation in a seed crystal fixing groove, assembling and sealing a front plate 5 and a back plate 6 through connecting flanges, and attaching heaters and temperature sensors in array to one outer side surface of an evaporation crystallizer,
S2, injecting saturated solution of a crystal material into a solution evaporation tank 1, covering a top of the solution evaporation tank with a semi-permeable membrane, and adjusting an arrayed electric heating temperature control device 14 according to the growth height of the crystal to meet growth temperature gradient distribution; and
S3, gradually reducing the solution in the solution evaporation tank 1 with evaporation until the solution is completely consumed, providing a growth driving force for the seed crystal 4 in a confined crystal growth tank 7 to continuously grow, simultaneously, limiting a growth space of the seed crystal 4 in a specific direction until the seed crystal grows into a large-sized single crystal with a special shape, and after growth, disassembling and separating the back plate 6 of the evaporation crystallizer to finally obtain a large-sized single crystal product required by a customer.

In an embodiment, the growth temperature gradient distribution is controlled: temperature sensors detect the temperatures and sends the measured temperature data to a microcomputer 13 in a Modbus RTU protocol through an RS485 interface, and the microcomputer 13 controls an output voltage of a DC power supply 12 through a compiled program according to the received temperature data, so as to change output powers of the heaters and finally achieve adjustment of temperature distribution. This ensures stability of the growth driving force in the crystal growth environment, thereby reducing probability of spontaneous nucleation in the solution, promoting transportation of solute raw materials in the solution to a surface of the crystal, and ensuring high-quality growth of the crystal with a sufficient height in a complete growth form.

In an embodiment, the computer program for controlling the DC power supply 12 ensures temperature control and management: the temperature corresponding to supersaturation of −10% to −15% at 12 cm to 15 cm above the crystallization surface gradually decreases to the temperature corresponding to supersaturation of 5% to 10%. The temperature control and management can optimally improve a growth rate of the crystal and ensure the growth quality.

In the present disclosure, multiple polyimide film heaters 9 are arranged in an array on the outside of the evaporation crystallizer, which is controlled by the DC power supply 12. An NTC10K thermistor sensor 10 is installed on the outside of each heater, and temperature data is sent to the microcomputer 13 through a temperature transmitter 11. The microcomputer 13 controls the output of the DC power supply 12 according to the temperature data, thereby changing a temperature gradient formed by the heaters in real time, controlling distribution of the growth driving force, and helping the steady growth of the large-sized KDP single crystals.

When the growth device in the present disclosure is applied, a ratio of a cross-sectional area of the solution evaporation tank 1 to a cross-sectional area of the confined crystal growth tank 7 needs to be determined by an evaporation rate of the solution at the operation temperature, so that the material supply rate and consumption rate for desired of supersaturation can be maintained, the growth driving force in the solution is ensured to be in a stable range, and the growth rate and the quality of the crystal are improved.

Embodiment 1: with reference to FIG. 1, it can be understood that a growth device for obtaining a large-sized single crystal material based on a solvent evaporation method includes a solution evaporation tank 1, in which growth solution 2 is filled. A flat groove at the bottom of the crystal growth device main body 3 is provided with a seed crystal 4 for growth. And the crystal growth device main body 3 includes the front plate 5 and the back plate 6 that are detachably connected to each other.

The crystal growth device main body 3 may be divided into a growth solution evaporation tank 1 and a confined crystal growth tank 7. The two tanks are connected by a funnel-shaped structure 8. Multiple polyimide film heaters 9 are connected to the crystal growth device main body 3, and form an arrayed electric heating temperature control device 14 together with an NTC10K thermistor sensor 10, a temperature transmitter 11, a DC power supply 12, and a microcomputer 13.

Working principle: when the present disclosure is used, the seed crystal 4 for growth is placed in the crystal growth device main body 3. The polyimide film heaters 9 are connected to the DC power supply 12, attached to and covered on an outer surface of the confined crystal growth tank 7 and the bottom of the growth solution evaporation tank 1, and arranged in an array at equal intervals from low to high positions. An NTC10K thermistor sensor 10 is attached to the outside of each heater, and is connected to the temperature transmitter 11, and is then connected to the microcomputer 13 through an RS485-to-USB cable. The NTC10K thermistor sensor 10 can obtain the temperature of the polyimide film heater 9 and feed the temperature back to the microcomputer 13 in time. The microcomputer 13 controls the output voltage of the DC power supply 12 through a serial port according to the real-time temperature data and the height of the crystal, so that the temperature distribution in the evaporation crystallizer can be gradually increased from the bottom to the top. In this way, the supersaturation can form gradient, and transportation of raw materials can be promoted, so that the seed crystal 4 can begin to grow.

In the above technical solution, a rectangular groove 15, that is, a seed crystal fixing groove, is arranged at the bottom center of the front plate 5 and the back plate 6 of the crystal growth device main body, in which the seed crystal 4 is placed, as shown in FIG. 2. The size of the rectangular groove 15 is 2 mm in width×2 mm in depth.

Working principle: when the present disclosure is used, the placement position of the seed crystal 4 is ensured to be more accurate and stable through the rectangular groove 15. And after the seed crystal is placed, the front plate 5 and the back plate 6 of the crystal growth device are connected and sealed through flanges.

In the foregoing technical solution, a directional growth method for improving a growth quality and a utilization rate of a large-sized KDP single crystal is included, and a specific process includes the following steps:
Step 1, growth solution 2 with a mass fraction of 24.5% is prepared using raw materials of KH₂PO₄ powder (analytically pure) and solvent high-purity deionized water (resistivity >17.5 mΩ/cm), the growth solution 2 is filtered by commercially available polyethersulfone resin microporous membrane with a pore size of 0.1 μm and double-layer flat filter with a pore size of 0.05 μm in sequence, and an overheating process is performed at a temperature which is 15° C. higher than a saturation point for 24 hours;
Step 2, the seed crystal 4 is placed in the rectangular groove 15 at the bottom of the front plate 5 and the back plate 6, the front plate 5 and the back plate 6 are connected through flanges to form the crystal growth device main body 3 after accurate fixation of the seed crystal 4, and the crystal growth device main body 3 is preheated by using an arrayed electric heating temperature control device 14 consisting of polyimide film heaters 9, NTC10K thermistor sensors 10, a temperature transmitter 11, a DC power supply 12, and a microcomputer 13 until the seed crystal 4 is preheated to a stable state at a temperature which is 1° C. higher than a set saturation point and is kept for at least 24 hours;
Step 3, the growth solution 2 is transferred to the solution evaporation tank 1, and the temperatures of the polyimide film heaters 9 at the bottom of the funnel-shaped solution evaporation tank 1 are adjusted through the microcomputer 13, so that the growth solution 2 increases to 6° C. above the saturation temperature and starts to evaporate to obtain the growth driving force, in which the seed crystal 4 performs controllable and stable growth in a two-dimensional direction in the confined crystal growth tank 7 at a specific speed;
Step 4, a horizontal size and a vertical size of the seed crystal 4 are recorded and calculated, and the temperature of each of the polyimide film heaters 9 is adjusted according to an actual height of the seed crystal 4, so that the polyimide film heaters 9 at the bottom of the growth solution evaporation tank 1 are kept at 42° C., the polyimide film heaters 9 near the surface of the crystal are lowered to 36° C., the polyimide film heaters 9 at a middle height are set to have a temperature uniformly decreasing from top to bottom according to a gradient, and the crystal growth rate should be controlled at 10 mm/day; and
Step 5: after the seed crystal 4 grows to an expected size, the temperatures of all polyimide film heaters 9 are adjusted through the microcomputer 13 to slowly decrease at a cooling rate of 0.1° C./h. After the temperatures decrease to the ambient temperature, the G-shaped clamps of the flanges on the outside of the crystal growth device main body 3 are removed, so that the front plate 5 and the back plate 6 are disassembled and separated. The seed crystal 4 can be removed from the crystal growth device main body 3, and finally a laminar KDP crystal with a large size of 400×400×12 mm³ and growing in a specific direction is obtained.

A conventional method requires more than 1790 kg of raw material solution to produce a large-sized KDP crystal with a size of 400×400×12 mm³ for a second harmonic generation converter. After using the design of the above solution, the demand for raw material solution may be reduced to 35.9 kg. According to the method of the present disclosure, a utilization rate of raw materials is close to 100%, and a large-sized oriented crystal that expands and grows along a specific phase matching direction can be obtained at a high speed. While a large-sized KDP crystal with a higher growth rate and a higher utilization rate is obtained, mechanical processing damage in the later stage is avoided, thereby improving a yield of crystals, shortening a growth period, significantly reducing growth costs, and having a considerable industrial production value and an economic benefit.

The technical features of the foregoing embodiments can be combined arbitrarily. In order to make the description concise, not all possible combinations of the technical features in the foregoing embodiments are described. However, as long as there is no contradiction between the combinations of the technical features, the combinations should be considered as the scope described in this specification.

What is claimed is:

1. A growth device for obtaining a large-sized single crystal material based on a solvent evaporation method, comprising: an evaporation crystallizer and an arrayed electric heating temperature control device, wherein
the evaporation crystallizer comprises a solution evaporation tank, a crystal growth tank, and a funnel-shaped structure through which the solution evaporation tank communicates with the crystal growth tank, wherein a cavity for containing growth solution is formed in the evaporation crystallizer, an upper part of the solution evaporation tank has an opening, a seed crystal fixing groove is arranged at a bottom of the crystal growth tank, and a plate-shaped cavity is formed in the crystal growth tank; and
the arrayed electric heating temperature control device comprises heaters and temperature sensors, which are arranged in groups as a vertical array on an outer side of the evaporation crystallizer.

2. The growth device for obtaining the large-sized single crystal material based on the solvent evaporation method according to claim 1, wherein an interval between the heaters in the vertical array is not more than 3 cm.

3. The growth device for obtaining the large-sized single crystal material based on the solvent evaporation method according to claim 2, wherein the heaters are polyimide film heaters with a width of no more than 2 cm.

4. The growth device for obtaining the large-sized single crystal material based on the solvent evaporation method according to claim 3, wherein the heaters are connected to a DC power supply, the temperature sensors establish signal connection with a microcomputer through a temperature transmitter, and the DC power supply is connected to the microcomputer.

5. The growth device for obtaining the large-sized single crystal material based on the solvent evaporation method according to claim 4, wherein the temperature sensors are thermistor sensors, and the thermistor sensors are attached to outer sides of the heaters.

6. The growth device for obtaining the large-sized single crystal material based on the solvent evaporation method according to claim 1, wherein the opening of the solution evaporation tank is covered with a semi-permeable membrane, and a pore size of the semi-permeable membrane is less than 100 nanometers.

7. The growth device for obtaining the large-sized single crystal material based on the solvent evaporation method according to claim 1, wherein the evaporation crystallizer comprises a front plate and a back plate connected through flanges.

8. A single crystal directional growth method, comprising the following steps:
S1, placing a seed crystal in a seed crystal fixing groove, assembling and sealing a front plate and a back plate through connecting flanges, and attaching heaters and temperature sensors in array to an outer side surface of an evaporation crystallizer,
S2, injecting saturated solution of a crystal material into a solution evaporation tank, covering a top of the solution evaporation tank with a semi-permeable membrane, and adjusting an arrayed electric heating temperature control device according to a growth height of a crystal to meet growth temperature gradient distribution; and
S3, gradually reducing the saturated solution in the solution evaporation tank with evaporation until the saturated solution is completely consumed, providing a growth driving force for the seed crystal in a confined crystal growth tank to continuously grow, simultaneously, limiting a growth space of the seed crystal until the seed crystal grows into a large-sized single crystal, and after growth, disassembling and separating the back plate of the evaporation crystallizer to finally obtain a large-sized single crystal product required by a customer.

9. The single crystal directional growth method according to claim 8, wherein adjusting an arrayed electric heating temperature control device according to a growth height of a crystal to meet growth temperature gradient distribution comprises: detecting temperatures through the temperature sensors and sending measured temperature data to a microcomputer in a Modbus RTU protocol through an RS485 interface, controlling an output voltage of a DC power supply by the microcomputer through a compiled program according to received temperature data to change output powers of the heaters and finally achieve adjustment of temperature distribution.

10. The single crystal directional growth method according to claim 9, wherein the compiled program for controlling the DC power supply needs to achieve temperature distribution as follows: a temperature corresponding to supersaturation of −10% to −15% at 12 cm to 15 cm above the crystal gradually decreases to a temperature corresponding to supersaturation of 5% to 10% on a surface of the crystal.
